(19) United States
(12) Patent Application Publication
(10) Pub. No.: US 2006/0148145 A1
(43) Pub. Date: Jul. 6, 2006

(54) Method of manufacturing an RF MOS semiconductor device

(75) Inventor: Yeo-Jo Yun, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/320,334

(22) Filed: Dec. 29, 2005

(30) Foreign Application Priority Data
Dec. 30, 2004 (KR) 10-2004-0117150

(51) Int. Cl. H01L 21/338; H01L 21/8238; H01L 21/44

(52) U.S. Cl. 438/184; 438/199; 438/683

(57) ABSTRACT

A method of manufacturing an RF MOS semiconductor device includes: forming a gate stack including a gate oxide layer and a gate polysilicon layer on a silicon substrate; forming source/drain regions aligned with both sidewalls of the gate stack in the silicon substrate; forming spacers on both sidewalls of the gate stack, the spacers exposing upper parts of both sidewalls of the gate polysilicon layer; and forming metal silicide layers on a surface of the source/drain, a surface of the gate polysilicon layer, and the exposed upper parts of both sidewalls of the gate polysilicon layer.

### CROSS-REFERENCE TO RELATED APPLICATION

This application claims the benefit of priority of Korean Patent Application No. 10-2004-0117150 filed in the Korean Intellectual Property Office on Dec. 30, 2004, the entire contents of which are incorporated herein by reference.

### BACKGROUND

(a) Technical Field

The present invention relates to a method of manufacturing a semiconductor device. More particularly, the present invention relates to a method of manufacturing an RF MOS semiconductor device.

(b) Description of the Related Art

A radio frequency (RF) MOS semiconductor device exhibits excellent frequency response characteristics, but has poor noise characteristics and power gain characteristics at high frequencies. More particularly, because gate series resistance, an important factor for determining the noise characteristic, is proportionally increased as the size of a semiconductor device is reduced, it is difficult to enhance the noise characteristics.

FIG. 1 to FIG. 7 are cross-sectional views showing a conventional method of manufacturing an RF MOS semiconductor device.

Referring to FIG. 1, an active region is defined by forming a trench oxide layer 14 on a silicon substrate 10 including an NMOS region and a PMOS region.

A gate stack 20 is formed by sequentially forming a gate oxide layer 16 and a gate polysilicon layer 18 on the active region of the silicon substrate 10. The gate polysilicon layer 18 is formed to a thickness of about 2000 Å. As shown in FIG. 1, a liner layer 12 is formed in an inner wall of a trench.

Referring to FIG. 2, a first oxide layer 22 is formed by oxidizing the silicon substrate 10 including the gate stack 20. Subsequently, the PMOS region in the silicon substrate 10 is covered by a first photoresist pattern 24, and then a shallow N− impurity region (N-type LDD region) 26 is formed by implanting N-type impurities into the NMOS region. The N− impurity region 26 is aligned with both sidewalls of the gate stack 20 in the NMOS region.

Referring to FIG. 3, after removing the first photoresist pattern 24, a second oxide layer 32 is formed on an entire surface of the silicon substrate 10, and then the NMOS region in the silicon substrate 10 is covered by a second photoresist pattern 28. Subsequently, a shallow P− impurity region (P-type LDD region) 30 is formed on the silicon substrate 10 by implanting P-type impurities into the PMOS region. The P-impurity region 30 is aligned with both sidewalls of the gate stack 20 in the PMOS region. Even though it is described above that P-type impurities are implanted after forming the second oxide layer 32, P-type impurities may be implanted before forming the second oxide layer 32 in some cases.

Referring to FIG. 4, the second photoresist pattern 28 is removed. Subsequently, an anisotropic etching is performed for a nitride layer which is formed on the entire surface of the silicon substrate 10. Accordingly, a spacer including the first oxide layer 22, the second oxide layer 32, and a nitride layer pattern 34 is formed at both sidewalls of the gate stack 20.

Referring to FIG. 5, the PMOS region in the silicon substrate 10 is covered by a third photoresist pattern 36, and then an N+ impurity region 38 having a large depth is formed on the silicon substrate 10 by implanting N-type impurities into the NMOS region. The N+ impurity region 38 is aligned with both sidewalls of the gate stack 20 in the NMOS region.

Accordingly, a source/drain in the NMOS region is composed of the N-impurity region 26 and the N+ impurity region 38.

Referring to FIG. 6, the third photoresist pattern 36 is removed. Subsequently, the NMOS region in the silicon substrate 10 is covered by a fourth photoresist pattern 40, and then a P+ impurity region 42 having a large depth is formed on the silicon substrate 10 by implanting P-type impurities into the PMOS region. The P+ impurity region 42 is aligned with both sidewalls of the gate stack 20 in the PMOS region. Accordingly, a source/drain in the PMOS region is composed of the P− impurity region 30 and P+ impurity region 42.

Referring to FIG. 7, the fourth photoresist pattern 40 is removed. Subsequently, a metal silicide 44 is formed on a surface of the gate polysilicon layer 18 and surfaces of the N−/P− impurity region 26 and 30 in order to form a contact in a later performed process.

According to a conventional method of manufacturing an RF CMOS semiconductor device, gate series resistance is reduced by forming the metal suicide only on the surface of the gate polysilicon layer 18. However, the reduction of the gate series resistance is limited.

### SUMMARY

Consistent with the present invention, there is provided a method of manufacturing an RF MOS semiconductor device having advantages of reducing series resistance of a gate in spite of a size reduction of a semiconductor device.

A method consistent with an embodiment of the present invention includes: forming a gate stack including a gate oxide layer and a gate polysilicon layer on a silicon substrate; forming a source/drain aligned with both sidewalls of the gate stack in the silicon substrate; forming a spacer on both sidewalls of the gate stack by exposing upper parts of both sidewalls of the gate polysilicon layer; and forming a metal silicide on a surface of the source/drain, a surface of the gate polysilicon layer, and the upper parts of both sidewalls of the gate polysilicon layer.

The metal silicide may be composed of cobalt silicide or titanium silicide.

A method consistent with another embodiment of the present invention includes: forming a gate stack including a gate oxide layer and a gate polysilicon layer on a silicon substrate including an NMOS region and a PMOS region; forming an N− impurity region and a P− impurity region both of which have smaller depths respectively in the NMOS region and the PMOS region, to be aligned to both sidewalls of the gate stack; forming a spacer on both sidewalls of the gate stack by exposing upper parts of both sidewalls of the gate polysilicon layer; forming an N+ impurity region and a P+ impurity region both of which have larger depths respectively in the NMOS region and the PMOS region, to be aligned to the spacer formed on both sidewalls of the gate stack; and forming a metal silicide on surfaces of the N−/P− impurity regions, a surface of the gate polysilicon layer, and the exposed upper parts of both sidewalls of the gate polysilicon layer.

The metal silicide may be formed by performing first and second heat treatments for a cobalt or titanium layer formed on the entire surface of the silicon substrate.

The metal silicide may be formed after forming the N+/P+ impurity regions.

The gate polysilicon layer may be formed to a thickness of about 3000 Å, and the spacer may be formed by anisotropically etching a nitride layer deposited on an entire surface of the substrate.

The spacer may be formed before or after forming the N+/P+ impurity region.

As described above, the gate series resistance can be reduced by additionally forming a metal silicide layer on the upper parts of both sidewalls of the gate polysilicon layer as well as on the surface of the gate polysilicon layer.

### BRIEF DESCRIPTION OF THE DRAWINGS

FIGS. 1 to 7 are cross-sectional views showing a conventional method of manufacturing an RF MOS semiconductor device.

FIGS. 8 to 14 are cross-sectional views showing a method of manufacturing an RF MOS semiconductor device consistent with embodiments of the present invention.

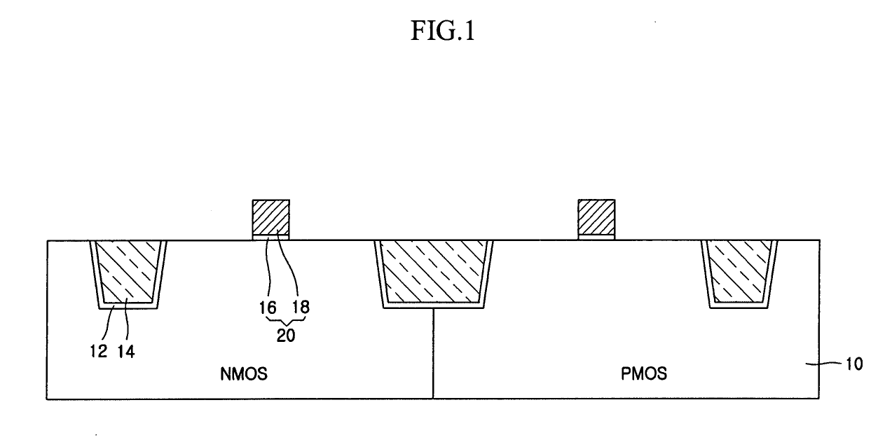

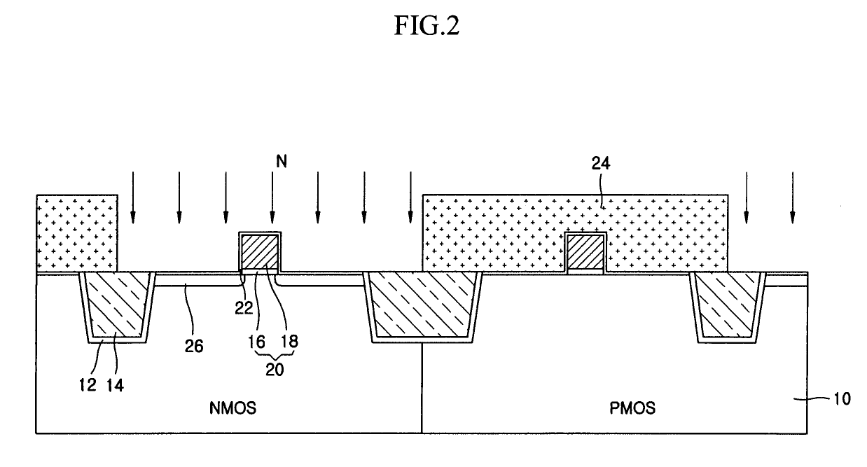

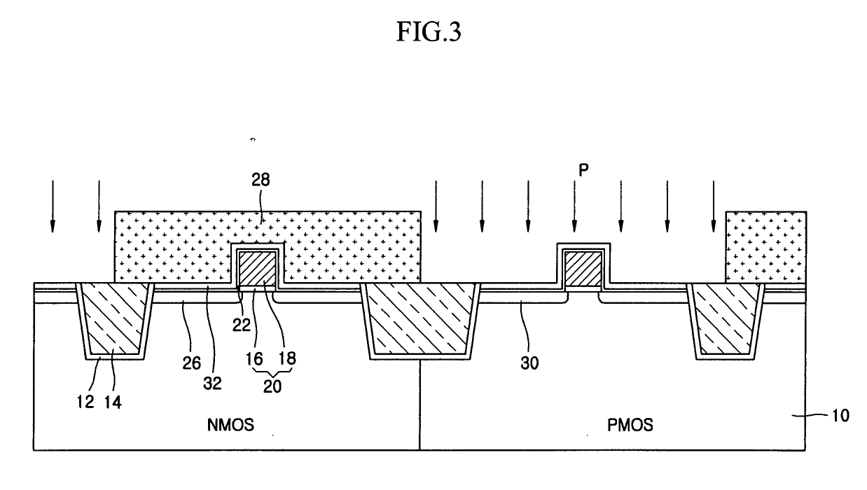

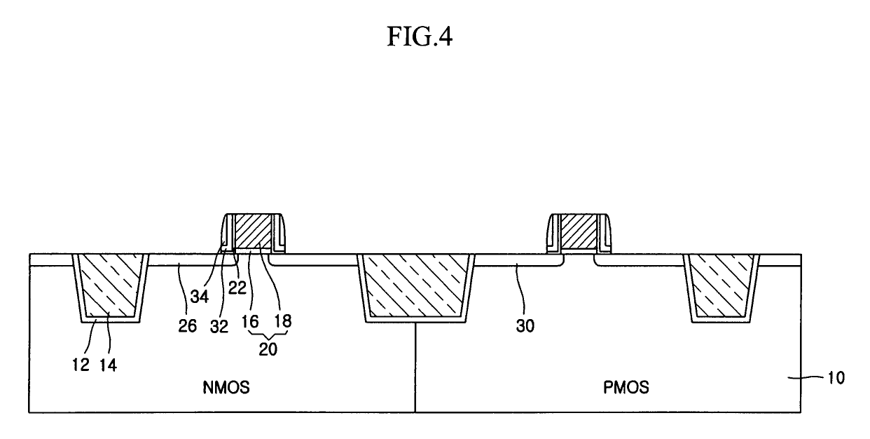

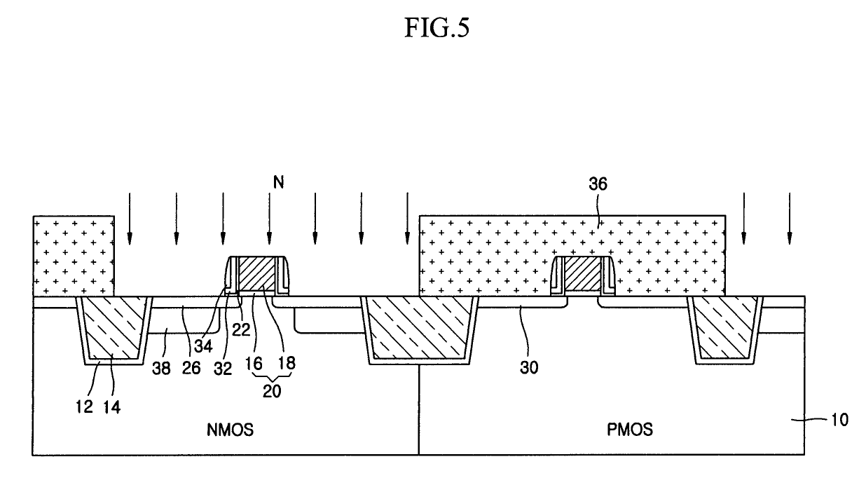

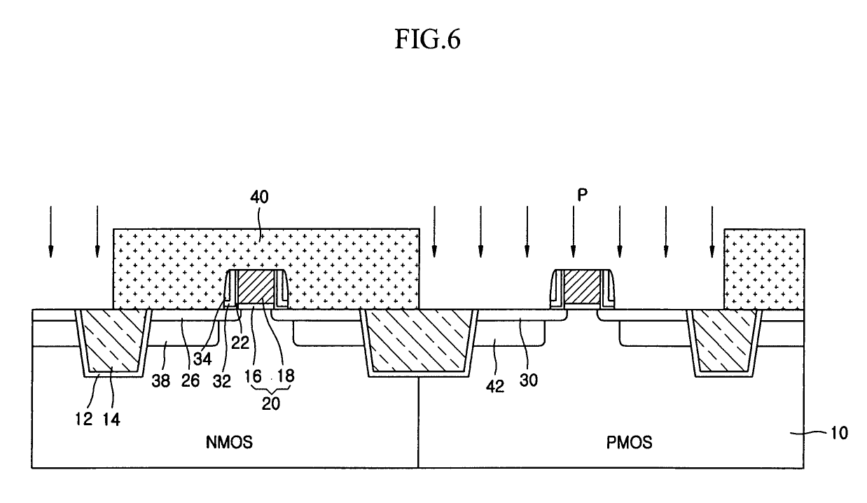

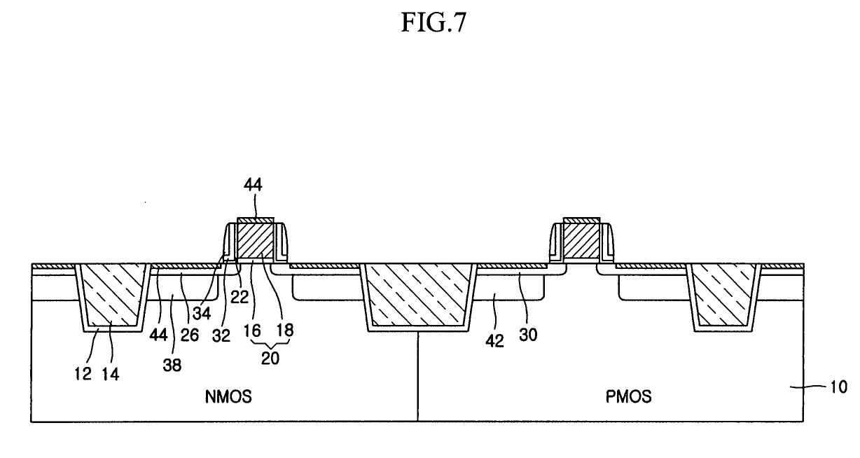

### DETAILED DESCRIPTION OF THE EMBODIMENTS

Embodiments consistent with the present invention will hereinafter be described in detail with reference to the accompanying drawings.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

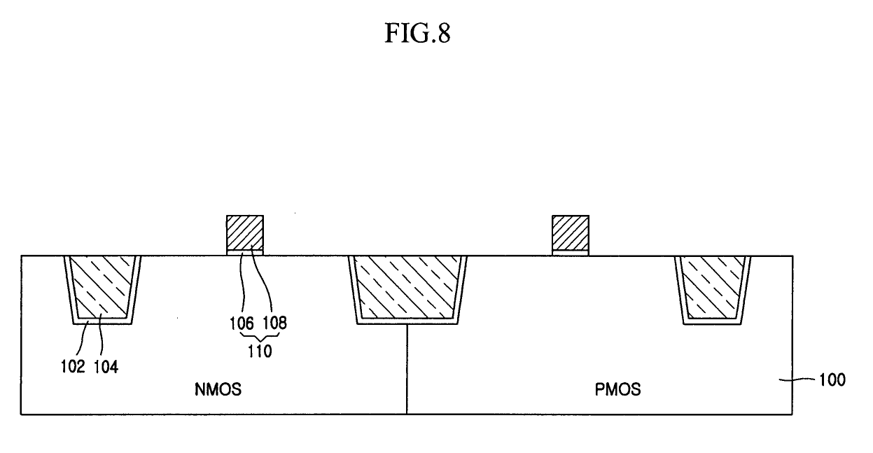

FIGS. 8 to 14 are cross-sectional views showing a method of manufacturing an RF MOS semiconductor device consistent with embodiments of the present invention.

Referring to FIG. 8, an active region is defined by forming a trench oxide layer 104 on a silicon substrate 100 including an NMOS region and a PMOS region. A gate stack 110 is formed by sequentially forming a gate oxide layer 106 and a gate polysilicon layer 108 on the active region of the silicon substrate 100. The gate polysilicon layer 108 is formed to a thickness of about 3000 Å, i.e., about 1000 Å thicker than the conventional gate polysilicon layer 18 discussed in the background section. As shown in FIG. 8, a liner layer 102 is formed on an inner wall of the trench in which trench oxide layer 104 is formed.

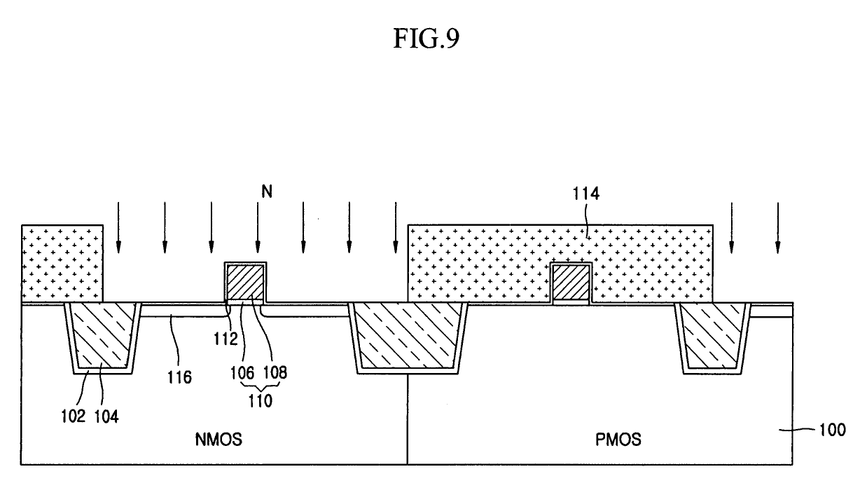

Referring to FIG. 9, a first oxide layer 112 is formed by oxidizing the silicon substrate 100 including gate stack 110. Subsequently, the PMOS region in the silicon substrate 100 is covered by a first photoresist pattern 114, and then a shallow N− impurity region (N-type LDD region) 116 is formed by implanting N-type impurities into the NMOS region. The N− impurity region 116 is aligned with both sidewalls of the gate stack 110 in the NMOS region.

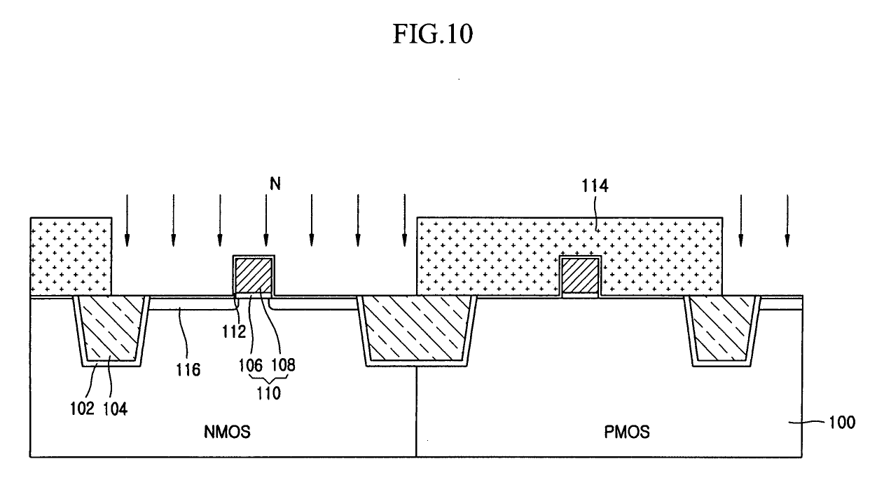

Referring to FIG. 10, after removing the first photoresist pattern 114, a second oxide layer 122 is formed on an entire surface of the silicon substrate 100, and then the NMOS region in the silicon substrate 100 is covered by a second photoresist pattern 118. Subsequently, a shallow P− impurity region (P-type LDD region) 120 is formed in the silicon substrate 100 by implanting P-type impurities into the PMOS region. The P− impurity region 120 is aligned with both sidewalls of the gate stack 110 in the PMOS region. In another embodiment consistent with the present invention, the P-type impurities may be implanted before forming the second oxide layer 122.

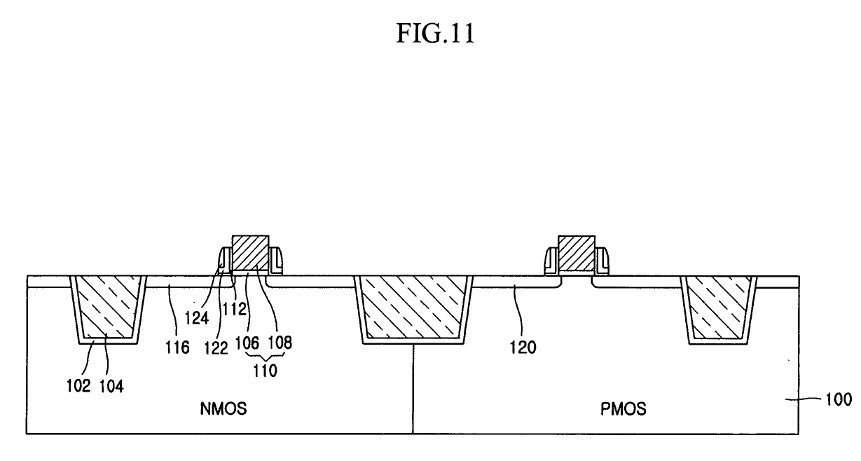

Referring to FIG. 11, the second photoresist pattern 118 is removed. Subsequently, a nitride layer is formed on the entire surface of the silicon substrate 100. The nitride layer is then anisotropically etched. Accordingly, a spacer including the first oxide layer 112, the second oxide layer 122, and a nitride layer pattern 124 is formed at both sidewalls of the gate stack 110.

However, according to an exemplary embodiment consistent the present invention, when the spacer is formed at both sidewalls of the gate stack 110, the nitride layer is etched such that upper parts of both sidewalls of the gate stack 110 may be exposed. In the meantime, the portion of the gate polysilicon layer 108 covered by the spacer is thicker than the conventional gate polysilicon layer. When etching the nitride layer, the first oxide layer 112 and second oxide layer 122 at the upper part of both sidewalls of the gate stack 110 may be simultaneously etched. Alternatively, the first oxide layer 112 and the second oxide layer 122 at the upper parts of both sidewalls of the gate stack 110 may be separately etched after the etching of the nitride layer.

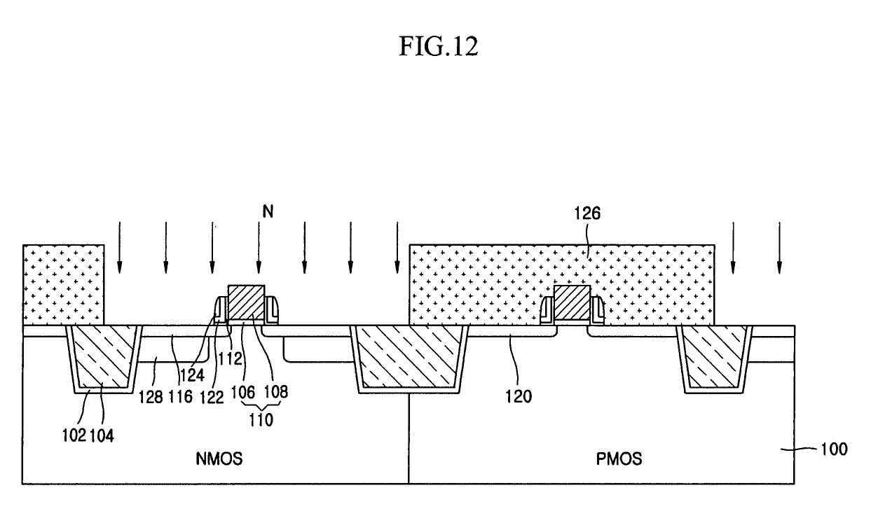

Referring to FIG. 12, the PMOS region in the silicon substrate 100 is covered by a third photoresist pattern 126, and then a deep N+ impurity region 128 is formed in the silicon substrate 100 by implanting N-type impurities into the NMOS region. The N+ impurity region 128 is aligned with the spacer formed at both sidewalls of the gate stack 110 in the NMOS region. Accordingly, a source/drain in the NMOS region is composed of the N− impurity region 116 and N+ impurity region 128.

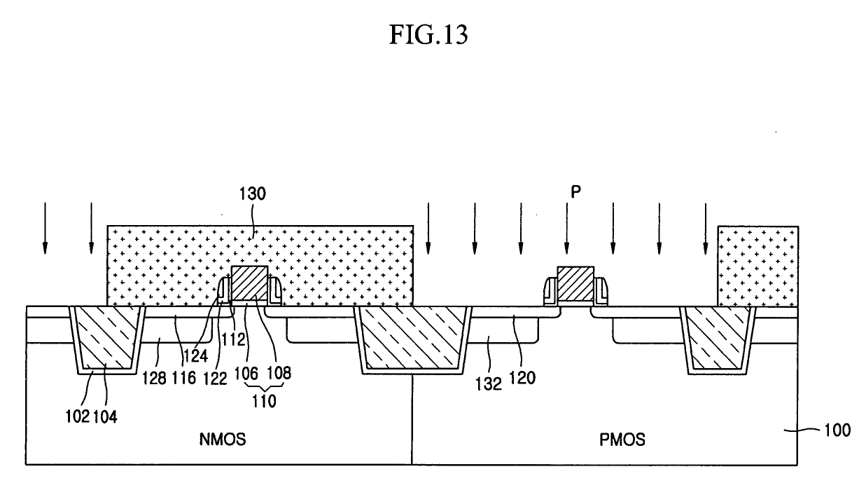

Referring to FIG. 13, the third photoresist pattern 126 is removed. Subsequently, the NMOS region in the silicon substrate 100 is covered by a fourth photoresist pattern 130, and then a deep P+ impurity region 132 is formed in the silicon substrate 100 by implanting P-type impurities into the PMOS region. The P+ impurity region 132 is aligned with the spacer and is formed at both sidewalls of the gate stack 110 in the PMOS region. Accordingly, a source/drain in the PMOS region is composed of the P− impurity region 120 and the P+ impurity region 132.

In the above description, upper parts of both sidewalls of the gate polysilicon layer 108 are exposed by etching the oxide layer and the nitride layer before forming the N+ impurity region 128 and P+ impurity region 132. However, upper parts of both sidewalls of the gate polysilicon layer 108 may also be exposed after forming the N+ impurity region 128 and P+ impurity region 132.

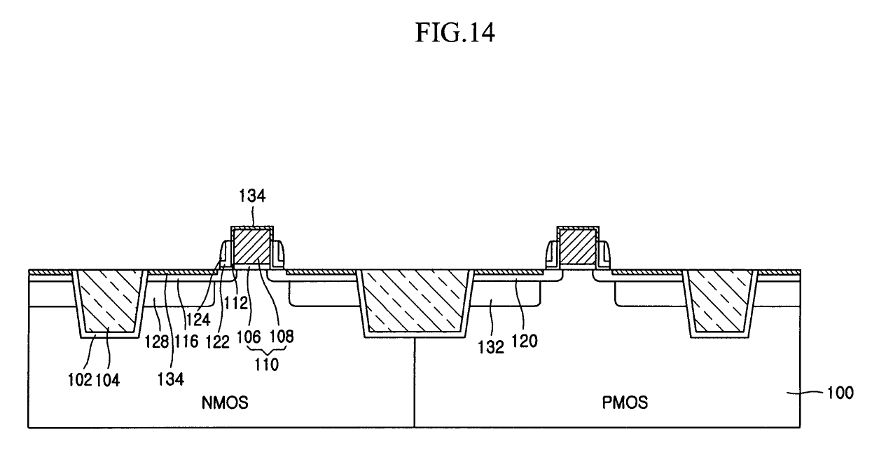

Referring to FIG. 14, the fourth photoresist pattern 130 is removed. Subsequently, a metal silicide 134 is formed on the surface of the gate polysilicon layer 108, the upper parts of both sidewalls of the gate polysilicon layer 108, and surfaces of the N−/P− impurity region 116 and 120. The metal silicide layer 134 may be composed of a cobalt silicide layer or a titanium silicide layer, and may be formed by the following processes. Firstly, a cobalt layer or titanium layer is formed on an entire surface of the silicon substrate 100 and allowed to react with silicon in exposed portions of gate polysilicon layer 108 and silicon substrate 100 through a first heat treatment, and then a portion of the metal layer which is not reacted with the first heat treatment is removed by an etchant. Next, the metal silicide is finally formed by performing a second heat treatment for the metal layer.

Consistent with the embodiments of the present invention, the metal silicide 134 is formed not only on the surface of the gate polysilicon layer 108, but also on the upper parts of both sidewalls of the gate polysilicon layer 108.

Therefore, gate series resistance may be reduced because the area of the metal silicide 134 is extended. Consequently, noise characteristics and power gain characteristics with respect to frequency may be enhanced due to the reduction of the gate series resistance.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing an RF MOS semiconductor device, comprising:
forming a gate stack including a gate oxide layer and a gate polysilicon layer on a silicon substrate, the gate stack including sidewalls;
forming source/drain regions aligned with the sidewalls of the gate stack in the silicon substrate;
forming spacers on the sidewalls of the gate stack, the spacers exposing upper parts of the sidewalls of the gate polysilicon layer;
forming metal silicide layers on a surface of the source/drain regions, a surface of the gate polysilicon layer, and the exposed upper parts of the sidewalls of the gate polysilicon layer.

2. The method of claim 1, wherein forming the metal silicide layers comprises forming metal silicide layers including cobalt silicide or titanium silicide.

3. A method of manufacturing an RF MOS semiconductor device, comprising:
forming a gate stack including a gate oxide layer and a gate polysilicon layer on a silicon substrate including an NMOS region and a PMOS region, the gate stack having sidewalls;
forming N− impurity regions in the NMOS region and P− impurity regions in the PMOS region, the N− impurity regions and the P− impurity regions being shallow and being aligned with the sidewalls of the gate stack;
forming spacers on the sidewalls of the gate stack, the spacers exposing upper parts of the sidewalls of the gate polysilicon layer;
forming N+ impurity regions in the NMOS region and P+ impurity regions in the PMOS region, the N+ impurity regions and the P+ impurity regions being deep and being aligned with the spacers formed on the sidewalls of the gate stack; and
forming metal silicide layers on surfaces of the N−/P− impurity regions, a surface of the gate polysilicon layer, and the exposed upper parts of both sidewalls of the gate polysilicon layer.

4. The method of claim 3, wherein forming the gate stack comprises forming the gate polysilicon layer at a thickness of about 3000 Å.

5. The method of claim 3, wherein forming the spacers comprises:
depositing a nitride layer on an entire surface of the silicon substrate; and
anisotropically etching the nitride layer.

6. The method of claim 3, wherein forming the spacers comprises forming the spacers before forming the N+/P+ impurity regions.

7. The method of claim 3, wherein forming the metal silicide layers comprises forming metal silicide layers including cobalt silicide or titanium suicide.

8. The method of claim 7, wherein forming the metal suicide layers comprises:
forming a cobalt layer or a titanium layer on an entire surface of the substrate;
performing a first heat treatment on the cobalt layer or the titanium layer;
etching a portion of the cobalt layer or the titanium layer that does not react in the first heat treatment; and
performing a second heat treatment on the cobalt layer or the titanium layer.

9. The method of claim 3, wherein forming the metal silicide layers comprises forming the metal silicide layers after forming the N+/P+ impurity regions.
